(19) United States
(12) Patent Application Publication
(10) Pub. No.: US 2023/0174419 A1
(43) Pub. Date: Jun. 8, 2023

(54) LOW-EMISSIVE MATERIAL COMPRISING AN INTERMEDIATE COATING COMPRISING TWO DIFFERENT LAYERS CONTAINING SILICON

(71) Applicant: SAINT-GOBAIN GLASS FRANCE, COURBEVOIE (FR)

(72) Inventors: Yann COHIN, PARIS (FR); Maëlis BANCI, BOURG-LA-REINE (FR); Corinne VICTOR, SAINT-LEU-LA-FORET (FR)

(21) Appl. No.: 17/924,081

(22) PCT Filed: May 7, 2021
(86) PCT No.: PCT/FR2021/050785

§ 371 Date: Nov. 8, 2022

(30) Foreign Application Priority Data
May 12, 2020 (FR) 2004681

(51) Int. Cl. C03C 17/36; C03C 17/34

(52) U.S. Cl. CPC C03C 17/3607; C03C 17/3435; C03C 2217/216; C03C 2217/256

(57) ABSTRACT

A material includes a transparent substrate coated with a stack including at least one silver-based functional metal layer and at least two dielectric coatings, each dielectric coating including at least one dielectric layer, so that each functional metal layer is placed between two dielectric coatings, wherein the dielectric coating located in contact with the substrate includes an intermediate coating including two different layers containing silicon, the two layers containing silicon consist of different chemical elements or composed of the same elements in different proportions.

The invention relates to a material comprising a transparent substrate coated with a stack comprising a silver-based functional metal layer. The invention also relates to the glazings comprising these materials and also to the use of such materials for manufacturing glazings.

Silver-based functional metal layers (or silver layers) have advantageous properties of electrical conduction and of reflection of infrared radiation (IR), hence their use in “solar control” glazings targeted at reducing the amount of solar energy entering and/or in “low-e” glazings targeted at reducing the amount of energy dissipated toward the outside of a building, a vehicle or a device.

These silver layers are deposited between coatings based on dielectric materials, which generally comprise several dielectric layers (hereinafter “dielectric coatings”), making it possible to adjust the optical properties of the stack. Furthermore, these dielectric layers make it possible to protect the silver layer from chemical or mechanical attacks.

The invention relates most particularly to a material used to manufacture a glazing used as a constituent element of a heating or cooling device.

A heating device comprises a chamber delimited by one or more walls and heating means so as to enable the chamber to be heated to a high temperature. The heating devices may particularly be selected from ovens, stoves, furnaces, etc. According to the invention, the heating means are separate from the stack of thin layers. Heated motor vehicle glazings, the stack of which serves as a heating element, do not correspond to a heating device according to the invention.

A cooling device comprises a chamber delimited by one or more walls and means making it possible to cool the chamber to a temperature below standard temperature (20° C.). Cooling devices may particularly be selected from:
refrigerators, for which the desired temperatures vary between 0 and 20° C. (positive cold),
freezers, for which the desired temperatures are less than 0° C. (negative cold).

The glazings used as constituent elements of a cooling device of freezer type (negative cold) are generally monolithic glass.

The glazings used as constituent elements of a heating or cooling device of refrigerator type (positive cold) are generally multiple glazings.

According to the invention, a multiple glazing comprises at least two substrates kept at a distance so as to delimit a space. The faces of the glazing are named, from the inside of the heating or cooling device by numbering the faces of the substrates from the inside (inner face) to the outside (outer face) of the heating or cooling device.

In the case of a multiple glazing for the heating device, the different substrates are generally arranged side by side in an open space.

In the case of a multiple glazing for a cooling device of refrigerator type, the different substrates are generally linked together so as to form a hermetic cavity between two substrates.

These glazings contribute to keeping the temperature inside the device at a setpoint temperature while keeping the outer surface of the glazing a usual level of cold to the touch, for the protection and comfort of the users.

The use of a substrate coated with a functional coating which reflects infrared radiation (IR) in glazings used as constituent elements of a heating or cooling device makes it possible:
to reduce the amount of energy dissipated to the outside, in the case of a heating device, by reflecting the heat toward the chamber,
to reduce the amount of energy entering the chamber, in the case of a cooling device, by reflecting the heat toward the outside.

The use of these coatings contributes to reducing the consumption of the heating or cooling device, and reducing the heating or cooling of the glazing.

The coatings comprising silver-based functional metal layers (or silver layers) have the best performance for reducing the emissivity of the glazings while retaining optical and aesthetic qualities. These coatings provide better protection of users, lower energy consumption and a greater ease of use.

However, the chemical and thermal resistance and mechanical strength of the coatings comprising these silver-based functional metal layers is often insufficient. This low resistance is reflected, during use under normal conditions, and even more so under more extreme conditions, in the appearance in the short term of defects such as corrosion points, scratches, or even the total or partial tearing away of the stack.

This phenomenon is accentuated when these glazings are used in heating devices, particularly when they are subjected to long and repeated high-temperature heat treatment cycles in a humid environment.

This phenomenon is also accentuated when these glazings are used in cooling devices, particularly when they are permanently subjected to a humid environment.

These extreme conditions further accelerate the degradation of the silver layers, particularly by dewetting or corroding the silver. All defects or scratches, whether due to corrosion or mechanical stresses, are liable to affect not only the energy and optical performance of the coated substrate, but also the appearance thereof.

The applicant has developed a functional coating which is most particularly suitable for these applications. This coating comprising a single silver-based functional layer protected by an underlayer and a blocking overlayer. The dielectric coatings surrounding the functional layer essentially consist of oxide-based layers.

This coating is most particularly suitable for cooling applications and heating devices, since it has both:
significant chemical durability, particularly with a resistance of greater than 56 days in a High Humidity Test, and
low emissivity (approximately 3%).

The excellent chemical durability may be attributable to the nature of its dielectrics, which are essentially oxides.

Nevertheless, to be able to be used in heating or cooling devices, the materials must undergo a high-temperature heat treatment, such as tempering. The functional coating developed by the applicant remains sensitive to overheating, both during tempering thereof and during the potential use thereof in a heating device. This sensitivity to the heat treatment could be due to the nature of its dielectrics, composed exclusively of oxides.

The silver-based functional layer is unstable and dewets during the high-temperature heat treatment. This dewetting is characterized by the appearance of holes in the silver layer. These holes are said to be dendritic, due to their often branched form. These holes in the silver layer have two highly detrimental consequences for the product.

The product becomes hazy (after tempering, since the edge of the holes in the silver layer scatters light). Visually, this haze corresponds to the appearance of a more or less milky mist. This haze may be inhomogeneous because it may reveal defects at the surface of the glass (drying marks, suction lifter marks from handling the glass, etc.).

The emissivity of the product, its key performance, is heavily degraded by these holes. Indeed, it can be shown that, in each hole, it is no longer the emissivity of the silver layer (for example 3%) which is to be taken into account, but rather that of the glass (close to 89%). Thus, while the holes represent just 1% of the surface area, the emissivity is already degraded by approximately 1.8 points, going from 3% to nearly 5%.

There are a certain number of patent applications disclosing silver-based functional layers comprising a low-index thin layer, which may be based on silicon oxide, in contact with the substrate. Among these applications, mention may be made of application EP1480920. The aim of these low-index layers is to reduce the haze following a heat treatment of stacks comprising a silver-based functional layer. These layers allegedly make it possible to reduce the negative impact of the aging of the glass substrate by “regenerating” the surface of a potentially degraded glass substrate, for example following long storage.

These patent applications do not relate to the issue of heating or cooling devices. The maximum thickness of these intermediate layers of silicon oxide is 10 nm. Finally, these applications do not disclose stacks consisting essentially of layers of oxide having an advantageous chemical durability.

The applicant has discovered, surprisingly, that this dual degradation of optics and emissivity may be largely done away with while retaining the very good chemical durability of the product. Indeed, some technical solutions enable a great improvement in the haze on tempering, but without preserving the chemical durability required for the material, which is then considerably weakened.

The solution of the invention consists in placing an intermediate coating, comprising at least two different layers comprising silicon in contact with the substrate, the two layers comprising silicon being composed of different chemical elements or being composed of the same elements in different proportions.

The superior resistance to heating in the presence of such an intermediate layer not only applies during tempering but also during use in a heating device.

For example, the use of the intermediate coating according to the invention has 8 times greater resistance to heating, at a temperature of 450° C., than that of the same functional coating without an intermediate coating. 8 times greater resistance means that the material provided with a stack comprising an intermediate coating can be heated at an identical temperature for 8 times longer than the same stack not containing the intermediate coating before exhibiting the same degree of degradation.

The applicant has discovered that there is a thickness range for this intermediate coating which should be observed so as to have an anti-haze effect and very good chemical durability. The advantageous effects of the invention are not obtained for thicknesses of less than 3 nm, 5 nm or 10 nm, depending on the nature of the silicon-comprising layers composing the intermediate coating.

In particular, the applicant has discovered that the use of the intermediate coating makes it possible to delay the degradation of the functional coating. Nevertheless, in order for this delayed degradation to be sufficient not to lead to degradation:
during a high-temperature heat treatment, that is at a temperature of greater than 550° C. for several minutes, or
during long and repeated heating cycles (lasting longer than 15 minutes) at a temperature of between 100° C. and 250° C., the intermediate coating must have a minimal thickness.

Indeed, by virtue of the intermediate coating of the invention, the time/temperature pair, during heating, becomes compatible with a transformation of the glass, such as tempering or bending, without haze or degradation of the emissivity. On the tempering and bending tools used, the glazing comprising a functional coating without an intermediate coating exhibits haze at time and temperature parameters which are very close to those required to obtain acceptable flatness, fragmentation and shape. The industrial tools used for bending and/or tempering the substrates comprising functional coatings may further exhibit some variability. A material must therefore be sufficiently robust to accommodate this process variability. The materials of the invention have this additional resistance. The observed delay in degradation (several dozen seconds at 705° C.) is sufficient to ensure that the materials will not be degraded, regardless of the variability of the tempering process.

The invention therefore relates to a material comprising a transparent substrate coated with a stack comprising at least one silver-based functional metal layer and at least two dielectric coatings, each dielectric coating comprising at least one dielectric layer, so that each functional metal layer is placed between two dielectric coatings, characterized in that the dielectric coating located in contact with the substrate comprises an intermediate coating located directly in contact with the substrate comprising at least two different layers comprising silicon, the two layers comprising silicon are composed of different chemical elements or composed of the same elements in different proportions.

The invention also relates:
to a glazing comprising a material according to the invention,
to a glazing comprising a material according to the invention mounted on a device, on a vehicle, particularly a motor vehicle, or on a building, and
to the process for preparing a material or a glazing according to the invention,
to the use of a glazing according to the invention as solar-control and/or low-emissivity glazing for buildings or vehicles,
to a building, vehicle or device comprising a glazing according to the invention.

The invention also relates to a heating or cooling device comprising heating or cooling means and a chamber delimited by one or more walls, at least one wall of which comprises at least one glazing comprising a material according to the invention.

The invention is most particularly suitable as a cooling device of freezer type. In this case, the glazing may consist of the material (monolithic glazing), preferably with the stack located on the face of the substrate in contact with the chamber.

The glazing of the invention is also suitable for all applications requiring the use of a stack comprising silver layers for which the resistance to repeated heat treatments and to corrosion in a humid environment under hot and cold conditions are key parameters. Mention may particularly be made of:
glazings for oven doors, whether pyrolytic or not,
glazings for insert doors for stoves,
glazings for fire doors,
glazings for heating elements such as radiators and towel dryers.

The invention also relates to the use of a glazing as a constituent element of a cooling device, of a heating device or of a fire door, the glazing comprising a material according to the invention.

The glazing may be selected from multiple glazings comprising at least two transparent substrates.

The glazing may also solely consist of the material according to the invention. In this case, it comprises just a single substrate. This is therefore a single glazing or monolithic glazing.

Throughout the description, the substrate according to the invention is regarded as laid horizontally. The stack of thin layers is deposited above the substrate. The meaning of the expressions “above” and “below” and “lower” and “upper” is to be considered with respect to this orientation. Unless specifically stipulated, the expressions “above” and “below” do not necessarily mean that two layers and/or coatings are positioned in contact with one another. When it is specified that a layer is deposited “in contact” with another layer or with a coating, this means that there cannot be one (or more) layer(s) inserted between these two layers (or layer and coating).

All the light characteristics presented in the description are obtained according to the principles and methods described in the European standard EN 410 relating to the determination of the light and solar characteristics of the glazings used in glass for the construction industry. It is considered that the sunlight entering a building goes from the outside to the inside.

The preferred characteristics which appear in the remainder of the description are applicable both to the material according to the invention and, where appropriate, to the glazings, devices or method according to the invention.

The material, that is the transparent substrate coated with the stack, is intended to be subjected to a high-temperature heat treatment. Consequently, the stack and the substrate have preferably been subjected to a high-temperature heat treatment such as tempering, annealing or bending.

The stack is deposited by magnetic-field-assisted cathode sputtering (magnetron method). According to this advantageous embodiment, all the layers of the stack are deposited by magnetic-field-assisted cathode sputtering.

The material and the glazing of the invention are transparent, that is non-opaque. According to an advantageous embodiment, the material or the glazing according to the invention has a light transmission of greater than 35%, greater than 40%, greater than 45% or greater than 50%.

Unless otherwise mentioned, the thicknesses alluded to in the present document are physical thicknesses and the layers are thin layers. Thin layer is understood to mean a layer having a thickness of between 0.1 nm and 100 micrometers.

The intermediate coating is placed in contact with the substrate.

The intermediate coating comprises at least two different layers comprising silicon, the two layers comprising silicon being composed of different chemical elements or being composed of the same elements in different proportions.

The intermediate coating may consist of layers comprising silicon.

Preferably, at least one layer comprising silicon is selected from layers based on silicon oxide comprising essentially oxygen and very little nitrogen and layers based on silicon oxynitride comprising a mixture of oxygen and nitrogen.

The intermediate coating has a thickness:
of greater than or equal to 3 nm, of greater than or equal to 5 nm, of greater than or equal to 8 nm, of greater than or equal to 10 nm or of greater than or equal to 15 nm,
of less than or equal to 50 nm, of less than or equal to 30 nm, of less than or equal to 20 nm or of less than or equal to 15 nm.

Preferably, the intermediate coating has a thickness of between 5 nm and 15 nm.

The layers comprising silicon may be selected from layers based on oxide, based on nitride or based on silicon oxynitride, such as layers based on silicon oxide, layers based on silicon nitride and layers based on silicon oxynitride.

Preferably, the intermediate coating comprises at least one layer based on oxide or a layer based on silicon oxynitride.

The layers comprising silicon may comprise, or consist of, elements other than silicon, oxygen and nitrogen. These elements may be selected from aluminum, boron, titanium and zirconium. Preferably, the elements are selected from aluminum, boron and titanium.

The layers comprising silicon may comprise at least 60%, at least 65%, at least 70%, at least 75.0%, at least 80%, or at least 90% by weight of silicon relative to the weight of all the elements forming the layer comprising silicon, other than nitrogen and oxygen.

Preferably, the layer comprising silicon comprises at most 35%, at most 20%, or at most 10% by weight of elements other than silicon relative to the weight of all the elements forming the layer comprising silicon, other than oxygen and nitrogen.

According to one embodiment, the layers comprising silicon comprise less than 35%, less than 30%, less than 20%, less than 10%, less than 5% or less than 1% by weight of zirconium relative to the weight of all the elements forming the layer based on silicon oxide, other than oxygen and nitrogen.

The layer comprising silicon may comprise at least 2%, at least 5.0%, or at least 8% by weight of aluminum relative to the weight of all the elements forming the layer based on silicon oxide, other than oxygen and nitrogen.

The amounts of oxygen and nitrogen in a layer are determined by atomic percentages relative to the total amounts of oxygen and nitrogen in the layer in question.

According to the invention:
the layers based on silicon oxide comprise essentially oxygen and very little nitrogen,
the layers based on silicon nitride comprise essentially nitrogen and very little oxygen,
the layers based on silicon oxynitride comprise a mixture of oxygen and nitrogen.

The layers based on silicon oxide comprise at least 90%, as atomic percentage, of oxygen relative to the oxygen and nitrogen in the layer based on silicon oxide.

The layers based on silicon nitride comprise at least 90%, as atomic percentage, of nitrogen relative to the oxygen and nitrogen in the layer based on silicon oxide.

The layers based on silicon oxynitride comprise 10 to 90% (limit values excluded), as atomic percentage, of nitrogen relative to the oxygen and nitrogen in the layer based on silicon oxide.

The layers based on silicon oxide are preferably characterized by a refractive index at 550 nm of less than or equal to 1.55.

The layers based on silicon nitride are preferably characterized by a refractive index at 550 nm of greater than or equal to 1.95.

The layers based on silicon oxynitride are preferably characterized by a refractive index at 550 nm which is intermediate between a non-nitrided layer of oxide and a non-oxidized layer of nitride. The layers based on silicon oxynitride preferably have a refractive index at 550 nm of greater than 1.55, 1.60 or 1.70 or of between 1.55 and 1.95, 1.60 and 2.00, 1.70 and 2.00 or 1.70 and 1.90.

These refractive indices may vary to a certain extent (±0.1) depending on the deposition conditions. Indeed, by altering certain parameters such as pressure or the presence of dopants, it is possible to obtain layers of greater or lesser density and therefore a variation in refractive index.

Each layer comprising silicon has a thickness of greater than or equal to 2 nm, of greater than or equal to 3 nm, of greater than or equal to 4 nm or of greater than or equal to 5 nm.

Each layer comprising silicon has a thickness of less than or equal to 25 nm, of less than or equal to 20 nm or of less than or equal to 15 nm.

The layer comprising silicon can be obtained
by cathode sputtering,
from a silicon metal target or optionally from a ceramic target based on silicon oxide.

According to one embodiment, the intermediate coating comprises a first layer comprising silicon based on silicon oxide, in contact with the substrate. Advantageously, the intermediate coating comprises a second layer comprising silicon selected from layers based on silicon nitride and on silicon oxynitride.

This solution has the considerable advantage that it requires very little modification of the stack which has already been developed by the applicant. Indeed, the use of a layer based on silicon oxide, which layer has an optical index close to that of glass, then requires no modification of the already-developed stack, since these layers are optically neutral. The light interference at the glass/SiO2 interface is negligible.

Only the second layer requires adaptation of the stack by reducing some of the thickness of the dielectric layers of the dielectric coating which it incorporates. Nevertheless, since the thickness of this layer can be low, approximately a few nanometers, the modification is insignificant.

According to another embodiment, the intermediate coating comprises at least one layer based on silicon nitride and a layer based on silicon oxynitride.

The intermediate coating may comprise a first layer comprising silicon based on silicon oxynitride, in contact with the substrate. In this case, the intermediate coating comprises a second layer comprising silicon selected from layers based on silicon nitride and on silicon oxide. Advantageously, the intermediate coating comprises a second layer comprising silicon based on silicon nitride.

The intermediate coating may comprise a first layer comprising silicon based on silicon nitride, in contact with the substrate. In this case, the intermediate coating comprises a second layer comprising silicon selected from layers based on silicon oxynitride and on silicon oxide.

The intermediate coating may comprise at least one layer based on silicon nitride and a layer based on silicon oxynitride.

The silver-based functional metal layer comprises, before or after heat treatment, at least 95.0%, preferably at least 96.5% and better still at least 98.0% by weight of silver relative to the weight of the functional layer.

Preferably, the silver-based functional metal layer comprises, before or after heat treatment, less than 5% or less than 1.0% by weight of metals other than silver, relative to the weight of the silver-based functional metal layer.

The thickness of the or each silver-based functional layer is from 5 to 30 nm, from 5 to 25 nm, or from 7 to 16 nm.

Preferably, the stack comprises just one functional layer. The stack in this case comprises just one functional layer and two dielectric coatings comprising at least one dielectric layer, so that each functional layer is placed between two dielectric coatings.

The stack may comprise at least two silver-based functional metal layers and at least three dielectric coatings comprising at least one dielectric layer, so that each functional layer is placed between two dielectric coatings.

The stack is located on at least one of the faces of the transparent substrate.

The stack can comprise blocking layers located below and/or above the silver-based functional metal layer.

The stack can comprise at least one blocking layer, the function of which is to protect the silver layers by preventing possible damage related to the deposition of a dielectric coating or related to a heat treatment. These blocking layers are preferably located in contact with the silver-based functional metal layers.

According to advantageous embodiments, the stack can comprise at least one blocking layer located below and directly in contact with a silver-based functional metal layer (blocking underlayer) and/or at least one blocking layer located above and directly in contact with a silver-based functional metal layer (blocking overlayer).

A blocking layer located above a silver-based functional metal layer is referred to as blocking overlayer. A blocking layer located below a silver-based functional metal layer is referred to as blocking underlayer.

The blocking layers are selected from metal layers based on a metal or on a metal alloy, metal nitride layers, metal oxide layers and metal oxynitride layers of one or more elements selected from titanium, nickel, chromium, tantalum and niobium, such as Ti, TiN, TiOx, Nb, NbN, NbOx, Ni, NiN, NiOx, Cr, CrN, CrOx, NiCr, NiCrN, NiCrOx.

When these blocking layers are deposited in the metal, nitride or oxynitride form, these layers can undergo a partial or complete oxidation according to their thickness and the nature of the layers which surround them, for example, during the deposition of the following layer or by oxidation in contact with the underlying layer.

The blocking layers may be selected from metal layers, in particular an alloy of nickel and chromium (NiCr) or titanium.

Advantageously, the blocking layers are metal layers based on nickel. The metal blocking layer based on nickel may comprise (before heat treatment) at least 20%, at least 30%, at least 40%, at least 50%, at least 60%, at least 70%, at least 80%, at least 90%, at least 95%, at least 96%, at least 97%, at least 98%, at least 99% or 100% by weight of nickel relative to the weight of the metal layer based on nickel.

The metal layers based on nickel may be selected from:
nickel metal layers,
doped nickel metal layers,
metal layers based on a nickel alloy.

The metal layers based on a nickel alloy can be based on a nickel-chromium alloy.

Each blocking layer has a thickness of between 0.1 and 5.0 nm. The thickness of these blocking layers may be:
at least 0.1 nm, at least 0.2 nm or at least 0.4 nm, and/or
at most 5.0 nm, at most 2.0 nm, at most 1.0 nm or at most 0.5 nm.

“Dielectric coating” within the meaning of the present invention should be understood as meaning that there may be just one layer or several layers of different materials inside the coating. A “dielectric coating” according to the invention predominantly comprises dielectric layers. However, according to the invention, these layers can also comprise layers of another nature, particularly absorbent layers, for example absorbent metal layers.

It is considered that the “same” dielectric layer is located:
between the substrate and the first functional layer,
between each silver-based functional metal layer,
above the final functional layer (the one furthest from the substrate).

“Dielectric layer” within the meaning of the present invention should be understood as meaning that, from the perspective of its nature, the material is “nonmetallic”, that is, is not a metal. In the context of the invention, this term denotes a material having an n/k ratio, over the whole visible wavelength range (from 380 nm to 780 nm) of equal to or greater than 5. n denotes the real refractive index of the material at a given wavelength and k represents the imaginary part of the refractive index at a given wavelength; the ratio n/k being calculated at a given wavelength which is identical for n and for k.

The thickness of a dielectric coating corresponds to the sum of the thicknesses of the layers which form it.

The coatings have a thickness of greater than 15 nm, preferably between 15 and 200 nm.

The dielectric layers of the coatings exhibit the following characteristics, alone or in combination:
they are deposited by magnetic-field-assisted cathode sputtering,
they are selected from oxides or nitrides of one or more elements selected from titanium, silicon, aluminum, zirconium, tin and zinc,
they have a thickness of greater than 2 nm, preferably between 2 and 100 nm.

Preferably, the silver-based functional layer is located above a dielectric layer referred to as stabilizing or wetting layer, made of a material which is able to stabilize the interface with the functional layer. These layers are generally based on zinc oxide.

Preferably, the silver-based functional layer is located below a dielectric layer referred to as stabilizing or wetting layer, made of a material which is able to stabilize the interface with the functional layer. These layers are generally based on zinc oxide.

The layers based on zinc oxide may comprise at least 80% or at least 90% by weight of zinc relative to the total weight of all the elements forming the layer based on zinc oxide, excluding oxygen and nitrogen.

The layers based on zinc oxide may comprise one or more elements selected from aluminum, titanium, niobium, zirconium, magnesium, copper, silver, gold, silicon, molybdenum, nickel, chromium, platinum, indium, tin and hafnium, preferably aluminum.

The layers based on zinc oxide may optionally be doped by means of at least one other element, such as aluminum.

The layer based on zinc oxide is a priori not nitrided, however traces may be present.

The layer based on zinc oxide comprises, in increasing order of preference, at least 80%, at least 90%, at least 95%, at least 98% or at least 100% by weight of oxygen relative to the total weight of oxygen and nitrogen.

The dielectric coating located between the substrate and the first functional metal layer and/or one or each dielectric coating located above the first silver-based functional layer located comprises a layer based on zinc oxide comprising at least 80% by weight of zinc relative to the weight of all the elements other than oxygen.

Preferably, each dielectric coating comprises a layer based on zinc oxide comprising at least 80% by weight of zinc relative to the weight of all the elements other than oxygen.

Preferably, the dielectric coating located directly below the silver-based functional metal layer comprises at least one dielectric layer based on zinc oxide, optionally doped using at least one other element, such as aluminum. The functional metal layer deposited above a layer based on zinc oxide is either directly in contact, or separated by a blocking layer.

In all the stacks, the dielectric coating closest to the substrate is referred to as lower coating and the dielectric coating furthest from the substrate is referred to as upper coating. The stacks containing more than one silver layer also comprise intermediate dielectric coatings located between the lower coating and the upper coating.

Preferably, the lower or intermediate coatings comprise a dielectric layer based on zinc oxide located below directly in contact with a silver-based metal layer, or separated from this layer by a blocking underlayer.

Preferably, the dielectric coating located directly above the silver-based functional metal layer comprises at least one dielectric layer based on zinc oxide, optionally doped using at least one other element, such as aluminum. The functional metal layer deposited below a layer based on zinc oxide is either directly in contact, or separated by a blocking layer.

Preferably, the intermediate or upper coatings comprise a dielectric layer based on zinc oxide located above and directly in contact with the silver-based metal layer, or separated from this layer by a blocking overlayer.

The zinc oxide layers have a thickness of:
at least 1.0 nm, at least 2.0 nm, at least 3.0 nm, at least 4.0 nm or at least 5.0 nm, and/or
at most 25 nm, at most 10 nm, or at most 8.0 nm.

The dielectric layers may have a barrier function. Dielectric layers having a barrier function (hereinafter barrier layer) is understood to mean a layer made of a material capable of forming a barrier to the diffusion of oxygen and water at high temperatures, originating from the ambient atmosphere or from the transparent substrate, toward the functional layer. Such dielectric layers are selected from layers:
based on compounds of silicon and/or of aluminum and/or of zirconium, selected from oxides such as SiO2, nitrides such as silicon nitrides Si3N4 and aluminum nitrides AlN, and oxynitrides SiOxNy, optionally doped using at least one other element,
based on zinc tin oxide,
based on titanium oxide.

Preferably, the material comprises one or more layers based on zinc tin oxide. The layers based on zinc tin oxide comprise at least 20% by weight of tin relative to the total weight of zinc and tin.

The layer based on zinc tin oxide comprises, relative to the total weight of zinc and tin, at least 20%, at least 30%, at least 40%, at least 50%, at least 60% or at least 80% by weight of tin.

Preferably, the layers based on zinc tin oxide comprise 40 to 80% by weight of tin relative to the total weight of zinc and tin.

The layer based on zinc tin oxide has a thickness:
of greater than 5 nm, greater than 10 nm, greater than 15 nm, greater than 20 nm, or greater than 25 nm,
of less than 50 nm, less than 40 nm, or less than 35 nm.

The dielectric coating located between the substrate and the first functional metal layer and/or one or each dielectric coating located above the first silver-based functional layer located comprises a layer based on zinc tin oxide comprising at least 20% by weight of tin relative to the total weight of zinc and tin. Each dielectric coating may comprise a layer based on zinc tin oxide comprising at least 20% by weight of tin relative to the total weight of zinc and tin.

According to the invention, layers based on oxides are considered to be oxidized layers which comprise predominantly oxygen (compared to nitrogen). Layers of nitrides and oxynitrides are not considered to be oxide layers.

The layers based on oxide according to the invention comprise, in increasing order of preference, at least 90%, as atomic percentage, of oxygen relative to the total amount of oxygen and nitrogen in the layer.

Preferably, the sum of the thicknesses of all the layers based on zinc tin oxide located in the dielectric coating located between the substrate and the first silver layer is greater than 30%, greater than 40%, greater than 50% or greater than 60% of the total thickness of the dielectric coating.

Preferably, the sum of the thicknesses of all the layers based on zinc tin oxide located in the dielectric coating located above a silver-based functional layer is greater than 50%, greater than 60%, greater than 70% or greater than 75% of the total thickness of the dielectric coating.

Preferably, the sum of the thicknesses of all the layers based on oxide present in the dielectric coating located between the substrate and the first functional metal layer is greater than 50%, greater than 55% or greater than 60% of the total thickness of the dielectric coating.

Preferably, the sum of the thicknesses of all the layers based on oxide present in each dielectric coating located above the first silver-based functional metal layer is greater than 50%, greater than 60%, greater than 70%, greater than 80% or greater than 90% of the total thickness of the dielectric coating.

Each dielectric coating located above the first silver-based functional layer may consist solely of oxide layer.

Preferably, the stack comprises at least one dielectric layer based on zinc oxide and a layer based on zinc tin oxide.

Preferably, the dielectric coating located directly below the silver-based functional metal layer comprises at least one dielectric layer based on zinc oxide and a layer based on zinc tin oxide.

Preferably, one or each dielectric coating located above the silver-based functional metal layer comprises at least one dielectric layer based on zinc oxide and a layer based on zinc tin oxide.

Preferably, each dielectric coating comprises at least one dielectric layer based on zinc oxide and a layer based on zinc tin oxide.

The stack of thin layers can optionally comprise a protective layer. The protective layer is preferably the final layer of the stack, that is to say the layer furthest from the substrate coated with the stack (before heat treatment).

The dielectric coating furthest from the substrate may comprise a protective layer. These layers generally have a thickness of between 0.5 and 10 nm, preferably 1 and 5 nm. This protective layer can be selected from a layer based on titanium, zirconium, hafnium, silicon, zinc and/or tin and a mixture thereof, this or these metals being in metal, oxidized or nitrided form.

According to one embodiment, the protective layer is based on zirconium and/or titanium oxide, preferably based on zirconium oxide, titanium oxide or titanium zirconium oxide.

According to one embodiment, the stack comprises:
a dielectric coating located below the silver-based functional metal layer,
optionally a blocking layer,
a silver-based functional metal layer,
optionally a blocking layer,
a dielectric coating located above the silver-based functional metal layer, optionally comprising a protective layer.

According to one embodiment, the stack comprises:
a dielectric coating located below the silver-based functional metal layer comprising the intermediate coating, a layer based on zinc tin oxide, and a layer based on zinc oxide,
optionally a blocking layer,
a silver-based functional metal layer,
optionally a blocking layer,
a dielectric coating located above the silver-based functional metal layer comprising a layer based on zinc oxide, a layer based on zinc tin oxide, and optionally a protective layer.

The substrate coated with the stack, or the stack alone, may be intended to undergo a heat treatment. The substrate coated with the stack may be bent and/or tempered. However, the present invention also relates to the coated substrate, not heat-treated.

The stack may not have undergone a heat treatment at a temperature of greater than 500° C., preferably 300° C.

The stack may have undergone a heat treatment at a temperature of greater than 300° C., preferably 500° C.

The heat treatments are selected from an annealing, for example from “Rapid Thermal Process” annealing, such as a laser or flash lamp annealing, a tempering and/or a bending. The rapid thermal annealing is for example described in application WO2008/096089.

The heat treatment temperature (at the stack) is greater than 300° C., preferably greater than 400° C. and better still greater than 500° C.

The substrate coated with the stack is preferably a tempered glass, particularly when it forms part of a glazing used as a constituent element of a cooling device, a heating device or a fire door.

The transparent substrates according to the invention are preferably made of a rigid inorganic material, such as made of glass, or are organic, based on polymers (or made of polymer).

The organic transparent substrates according to the invention can also be made of polymer, and are rigid or flexible. Examples of polymers which are suitable according to the invention comprise, in particular:
polyethylene,
polyesters, such as polyethylene terephthalate (PET), polybutylene terephthalate (PBT) or polyethylene naphthalate (PEN);
polyacrylates, such as polymethyl methacrylate (PMMA);
polycarbonates;
polyurethanes;
polyamides;
polyimides;
fluorinated polymers, such as fluoroesters, for example ethylene-tetrafluoroethylene (ETFE), polyvinylidene fluoride (PVDF), polychlorotrifluoroethylene (PCTFE), ethylene-chlorotrifluoroethylene (ECTFE), fluorinated ethylene-propylene copolymers (FEP);
photocrosslinkable and/or photopolymerizable resins, such as thiolene, polyurethane, urethane-acrylate, polyester-acrylate resins, and
polythiourethanes.

The substrate is preferably a sheet of glass or of glass-ceramic.

The substrate is preferably transparent, colorless (it is then a clear or extra-clear glass) or colored, for example blue, gray or bronze. The glass is preferably of soda-lime-silica type but it can also be a glass of borosilicate or alumino-borosilicate type.

According to a preferred embodiment, the substrate is made of glass, particularly soda-lime-silica glass, or of polymer organic material.

The substrate advantageously has at least one dimension greater than or equal to 1 m, indeed even 2 m and even 3 m. The thickness of the substrate generally varies between 0.5 mm and 19 mm, preferably between 0.7 and 9 mm, in particular between 2 and 8 mm, indeed even between 2.8 and 6 mm. The substrate may be flat or curved, indeed even flexible.

The invention also relates to a glazing comprising at least one material according to the invention. The invention relates to a glazing which may be in the form of a monolithic, laminated or multiple glazing, in particular double glazing or triple glazing.

The glazing may be a monolithic glazing comprising 2 faces.

The glazing may be a multiple glazing comprising two, three or four substrates. In this case, the glazing comprises a material according to the invention, comprising particularly a substrate and one, two or three additional substrates.

A multiple glazing comprises at least one material according to the invention and at least one additional substrate. The material and the additional substrate are either side by side or separated by at least one interlayer gas gap.

A double glazing comprises two substrates, an outer substrate and an inner substrate, and 4 faces.

A triple glazing comprises three substrates, an outer substrate, a central substrate and an inner substrate, and 6 faces.

In the case of a building, face 1 is outside the building and therefore constitutes the outer wall of the glazing. All the other faces are numbered in succession. The face located inside the building has the highest number.

A laminated glazing comprises at least one structure of first substrate/sheet(s)/second substrate type. The polymer sheet may particularly be based on polyvinyl butyral PVB, ethylene vinyl acetate EVA, polyethylene terephthalate PET, polyvinyl chloride PVC. The stack of thin layers is positioned on one at least of the faces of one of the substrates.

These glazings may be assembled on a building or a vehicle.

These glazings may be assembled on heating or cooling devices such as oven or refrigerator doors.

The glazing may comprise at least one transparent substrate coated with a functional coating other than a stack comprising at least one silver-based functional metal layer, such as a coating comprising a transparent conducting oxide (TCO). The coating comprising a transparent conducting oxide may be selected from a material based on indium tin oxide (ITO), based on zinc oxide doped with aluminum (ZnO:Al) or doped with boron (ZnO: B), or else based on tin oxide doped with fluorine (SnO2: F). These materials are deposited by a chemical route, for example by chemical vapor deposition (CVD), optionally plasma-enhanced (PECVD), or by a physical route, for example by deposition under vacuum by cathode sputtering, optionally magnetic-field-assisted (Magnetron). The presence of this other coating is particularly advantageous in the case of heating devices.

The functional coating other than a stack comprising at least one silver-based functional metal layer may be located on the same substrate. The functional coating other than a stack comprising at least one silver-based functional metal layer may be located on a substrate other than that coated by a stack comprising a silver-based functional metal layer. In this case, the glazing is a multiple glazing.

The glazing may thus comprise a functional coating other than a stack comprising a silver-based functional metal layer, such as a coating comprising a transparent conducting oxide, located:
on the substrate comprising a silver-based functional metal layer, on the face opposite that comprising the silver-based functional metal layer,
on one of the faces of a substrate other than that comprising a silver-based functional metal layer.

The heating device enables the heating of the chamber to a high temperature, particularly of greater than 50, 100, 200, 300, 400, 500 or 600° C. The heating device further comprises heating means. These heating means enable the chamber to be heated to a high temperature, particularly greater than 50, 100, 200, 300, 400, 500 or 600° C.

The following examples illustrate the invention.

### EXAMPLES

Stacks of thin layers defined below are deposited on substrates made of clear soda-lime glass with a thickness of 4 mm.

For these examples, the conditions of deposition of the layers deposited by sputtering (“magnetron cathode” sputtering) are summarized in table 1 below.

TABLE 1

| | | Pressure | | |
|---|---|---|---|---|
| Table | Targets employed | μbar | Gas | Index |
| Si3N4 | Si:Al 92/8% by wt | 2 | Ar 34%—N₂ 66% | 2.05 |
| SiON | Si:Al 92/8% by wt | 2 | Ar 15%—O₂ 9%—N₂ 76% | 1.7 |
| SiO2 | Si:Al 92/8% by wt | 2 | Ar 55%—O2 45% | 1.50 |
| SnZnO | Sn:Zn 60/40% by wt | 2 | Ar 25%—O₂ 75% | 2.05 |
| ZnO | Zn:Al(92/8%)Ox | 2 | Ar at 100% | 2.0 |
| NiCr | Ni:Cr (80:20% at.) | 2 | Ar at 100% | — |
| Ag | Ag | 4 | Ar at 100% | — |
| TiOx | TiOx | 2 | Ar at 100% | 2.35 |

at.: atomic;
wt: weight;
*: at 550 nm.

The materials and the physical thicknesses in nanometers (unless otherwise indicated) of each layer or coating of which the stacks are composed are listed in table 2 below as a function of their positions with regard to the substrate carrying the stack.

TABLE 2

| Glazing | | Cp-1 | Cp-2. | Inv. |
|---|---|---|---|---|
| DC | TiOx | 3 | 3 | 3 |
| | SnZnO | 41 | 41 | 41 |
| | ZnO | 7 | 7 | 7 |
| BL | NiCr | 0.4 | 0.4 | 0.4 |
| FL | Ag | 12.5 | 12.5 | 12.5 |
| | NiCr | 0.1 | 0.1 | 0.1 |
| DC | ZnO | 7 | 7 | 7 |
| | SnZnO | 30 | 30 | 30 |
| | Int. C | 0 | 5 | 10 |
| Sub. | Glass | — | — | — |

DC: Dielectric coating;
BL: Blocking layer;
FL: Functional layer;
Int. C: Intermediate coating.

A heat treatment is carried out on the coated substrates at 650° C. for 10 minutes.

Table 3 below lists the nature of the layers and the thicknesses of the intermediate coatings tested.

TABLE 3

| Intermediate coating | | Cp-1 | Cp-2 | Inv. 1 | Inv. 2 | Inv. 3 | Inv. 4 |
|---|---|---|---|---|---|---|---|
| 2nd layer | SiON | — | — | — | 5 nm | 5 nm | — |
| | Si₃N₄ | — | — | 5 nm | — | — | 5 nm |
| 1st layer | SiON | — | — | — | — | — | 5 nm |
| | Si₃N₄ | — | — | — | — | 5 nm | — |
| | SiO₂ | — | 5 nm | 5 nm | 5 nm | — | — |

The first layer corresponds to the layer in contact with the substrate and the second layer is deposited on this first layer.

Evaluation of Haze and Chemical Durability.

The level of haze is evaluated as follows. After heat treatment, the glass is placed on a desk inclined by 20 degrees relative to the vertical, in a room with black walls. It is illuminated by a powerful lamp placed vertically on the desk. The observer places themselves in front of the desk, 1 m away. In this configuration, a hazy sample exhibits a marked milky appearance: it scatters light from the lamp far from its zone of specular reflection on the glass. On the contrary, a sample not exhibiting haze does not scatter any light toward the observer: it therefore appears dark. The following assessment indicators were used:
“−”: The material is very hazy,
“0”: The material is hazy,
“+”: The material is not hazy.

The chemical durability is evaluated by a high-humidity (HH) test before and after heat treatment (HH-HT). The humidity (HH) test consists in storing samples at 90% relative humidity and at 60° C. for 56 days and in observing the possible presence of defects, such as corrosion pits. The following assessment indicators were used:
ok: no pits, the material does not have any defects after 56 days of testing,
nok: numerous pits, the material has defects and therefore does not pass the test.

The results are compiled in table 4 below.

TABLE 4

| Test | Cp-1 | Cp-2 | Inv-1 | Inv-2 | Inv-3 | Inv-4 |
|---|---|---|---|---|---|---|
| Haze | − | − | + | + | + | + |
| HH | ok | ok | ok | ok | ok | ok |
| HH-HT | ok | ok | ok | ok | ok | ok |

Study of the Degradation of the Emissivity as a Function of the Duration of the Heat Treatment

The applicant has discovered that the advantageous properties of the invention, from the perspective of resistance to heat treatments, can be attributed to delayed degradation. This delay is observed when the intermediate coating based on layers comprising silicon is used.

This delay is illustrated by comparative curves depicting the degradation of the emissivity in percentage points as a function of the duration of the heat treatment in seconds. The heat treatment is carried out at a temperature of 705° C. The material Cp-1 is compared, respectively, with the material Cp-2 and with the materials of the invention. In order to evaluate the delay in degradation, the duration of the heat treatment in seconds, for which 2 degradation points of emissivity is obtained, is compared between the material Cp-1, and, respectively, the material Cp-2 and the materials of the invention.

No significant delay in the degradation is observed for the material Cp-2. In contrast, for each material according to the invention, a delay of much greater than 30 s is observed.

Indeed, by virtue of the intermediate coating of the invention, the time/temperature pair, during heating, becomes compatible with a transformation of the glass, such as tempering or bending, without haze or degradation of the emissivity. On the tempering and bending tools used, the glazing Cp-1 exhibited haze at time and temperature parameters which are very close to those required to obtain acceptable flatness, fragmentation and shape. The industrial tools used to bend and/or temper a layered glazing may have variability. A glazing must therefore be sufficiently robust to accommodate this process variability. The materials of the invention have this additional resistance. The 30 seconds delay observed are sufficient to ensure that the materials will not be degraded, regardless of the variability of the tempering process.

Finally, when a treatment of 15 minutes is carried out at 630° C., the materials Cp-1 and Cp-2 are degraded. In particular, a degradation in the emissivity of more than 4 percentage points (relative to a base value of 3%) is observed. In comparison, no degradation in the emissivity is observed for the materials of the invention during a heat treatment at this temperature, even when the duration of the heat treatment is much longer (22 minutes).

1. A material comprising a transparent substrate coated with a stack comprising at least one functional metal layer comprising silver and at least two dielectric coatings, each dielectric coating comprising at least one dielectric layer, so that each functional metal layer is placed between two dielectric coatings, wherein the dielectric coating located in contact with the substrate comprises an intermediate coating located directly in contact with the substrate and comprising two different layers comprising silicon, the two different layers comprising silicon are composed of different chemical elements or composed of the same elements in different proportions.

2. The material according to claim 1, wherein the intermediate coating has a thickness greater than or equal to 10 nm.

3. The material according to claim 1, wherein the intermediate coating has a thickness less than or equal to 50 nm.

4. The material according to claim 1, the wherein a thickness of the or each silver based functional metal layer is from 7 to 30 nm.

5. The material according to claim 1, wherein the two different layers comprising silicon are selected from layers based on oxide, based on nitride or based on silicon oxynitride.

6. The material according to claim 1, wherein the intermediate coating comprises at least one layer based on oxide or a layer based on silicon oxynitride.

7. The material according to claim 1, wherein the intermediate coating comprises a first layer comprising silicon based on silicon oxide, in contact with the substrate.

8. The material according to claim 7, wherein the intermediate coating comprises a second layer comprising silicon selected from layers based on silicon nitride and on silicon oxynitride.

9. The material according to claim 1, wherein the intermediate coating comprises a first layer comprising silicon based on silicon oxynitride, in contact with the substrate.

10. The material according to claim 9, wherein the intermediate coating comprises a second layer comprising silicon selected from layers based on silicon nitride and on silicon oxide.

11. The material according to claim 1, wherein the intermediate coating comprises a first layer comprising silicon based on silicon nitride, in contact with the substrate.

12. The material according to claim 11, wherein the intermediate coating comprises a second layer comprising silicon selected from layers based on silicon oxynitride and on silicon oxide.

13. The material according to claim 1, wherein the intermediate coating comprises at least one layer based on silicon nitride and a layer based on silicon oxynitride.

14. The material according to claim 1, wherein the dielectric coating located between the substrate and a first functional metal layer of the at least one functional metal layer and/or one or each dielectric coating located above the first functional metal layer located comprises a layer based on zinc oxide comprising at least 80% by weight of zinc relative to the weight of all the elements other than oxygen.

15. The material according to claim 1, wherein the dielectric coating located between the substrate and a first functional metal layer of the at least one functional metal layer and/or one or each dielectric coating located above the first functional metal layer located comprises a layer based on zinc tin oxide comprising at least 20% by weight of tin relative to the total weight of zinc and tin.

16. The material according to claim 1, wherein the stack comprises at least one dielectric layer based on zinc oxide and a layer based on zinc tin oxide.

17. The material according to claim 1, wherein each dielectric coating comprises at least one dielectric layer based on zinc oxide and a layer based on zinc tin oxide.

18. The material according to claim 1, wherein a sum of thicknesses of all the oxide-based layers present in the dielectric coating located between the substrate and a first functional metal layer of the at least one functional metal layer is greater than 50% of a total thickness of the dielectric coating.

19. The material according to claim 1, wherein a sum of thicknesses of all the oxide-based layers present in each dielectric coating located above a first functional metal layer of the at least one functional metal layer is greater than 50% of the total thickness of the dielectric coating.

20. A glazing comprising a material according to claim 1 and one, two three additional substrates.

21. A heating or cooling device comprising a heater or cooler and a chamber delimited by one or more walls, wherein at least one wall of the one or more walls comprises at least one glazing comprising a material according to claim 1.
